(19) United States
(12) Patent Application Publication
(10) Pub. No.: US 2023/0288794 A1
(43) Pub. Date: Sep. 14, 2023

(54) REFLECTION-TYPE MASK BLANK FOR EUV LITHOGRAPHY, REFLECTION-TYPE MASK FOR EUV LITHOGRAPHY, AND MANUFACTURING METHODS THEREFOR

(71) Applicant: AGC Inc., Tokyo (JP)

(72) Inventors: Daijiro AKAGI, Tokyo (JP); Hirotomo KAWAHARA, Cupertino, CA (US); Kenichi SASAKI, Tokyo (JP); Ichiro ISHIKAWA, Tokyo (JP); Toshiyuki UNO, Tokyo (JP)

(73) Assignee: AGC Inc., Tokyo (JP)

(21) Appl. No.: 18/321,913

(22) Filed: May 23, 2023

Related U.S. Application Data
(63) Continuation of application No. PCT/JP2021/043502, filed on Nov. 26, 2021.

(30) Foreign Application Priority Data
Dec. 3, 2020 (JP) 2020-201198
Oct. 26, 2021 (JP) 2021-174692

(51) Int. Cl. G03F 1/24; G03F 1/54; G03F 1/48

(52) U.S. Cl. CPC G03F 1/24; G03F 1/54; G03F 1/48

(57) ABSTRACT

A reflective mask blank for EUV lithography, includes, in the following order, a substrate, a multilayer reflective film reflecting EUV light, a protective film for the multilayer reflective film, and an absorption layer absorbing EUV light, in which the protective film includes rhodium (Rh) or a rhodium material including Rh and at least one element selected from the group consisting of nitrogen (N), oxygen (O), carbon (C), boron (B), ruthenium (Ru), niobium (Nb), molybdenum (Mo), tantalum (Ta), iridium (Ir), palladium (Pd), zirconium (Zr), and titanium (Ti).

### CROSS-REFERENCE TO RELATED APPLICATIONS

This is a bypass continuation of International Patent Application No. PCT/JP2021/043502, filed on Nov. 26, 2021, which claims priority to Japanese Patent Application No. 2020-201198, filed on Dec. 3, 2020 and Japanese Patent Application No. 2021-174692, filed on Oct. 26, 2021. The contents of these applications are hereby incorporated by reference in their entireties.

### TECHNICAL FIELD

The present invention relates to a reflective mask blank for extreme ultra violet (EUV) lithography (hereinafter, referred to as an “EUV mask blank” in the present description), a reflective mask for EUV lithography, and manufacturing methods thereof.

### BACKGROUND ART

In the related art, a photolithography method using visible light or ultraviolet light has been used in a semiconductor industry as a technique for transferring a fine pattern, which is necessary for forming an integrated circuit including a fine pattern on an Si substrate or the like. However, while miniaturization of a semiconductor device is accelerated, a limit of the photolithography method in the related art is approaching. In the case of the photolithography method, a resolution limit of a pattern is about ½ of an exposure wavelength. It is said that the limit is ¼ of an exposure wavelength even in the case where a liquid immersion method is used, and the limit is expected to be about 20 nm or more and 30 nm or less even in the case where a liquid immersion method using an ArF laser (193 nm) is used. Therefore, EUV lithography with an exposure technique using EUV light having a wavelength shorter than that of an ArF laser is expected as an exposure technique for 20 nm or more and 30 nm or less. In this description, EUV light refers to light having a wavelength in a soft X-ray region or a vacuum ultraviolet region. Specifically, it refers to light having a wavelength of about 10 nm or more and 20 nm or less, particularly about 13.5 nm±0.3 nm.

The EUV light is easily absorbed by various substance, and a refractive index of the substance is close to 1 at this wavelength. Therefore, it is impossible to use a refractive optical system such as the photolithography using visible light or ultraviolet light in the related art. Therefore, in the EUV lithography, a reflective optical system, that is, a reflective mask and a mirror are used.

The mask blank is a laminate before patterning used for manufacturing a photomask. The EUV mask blank has a structure in which a multilayer reflective film that reflects EUV light, a protective film, and an absorption layer that absorbs EUV light are formed in this order on or above a substrate such as glass. The protective film protects the multilayer reflective film when a transfer pattern is formed on the absorption layer by a dry etching process. As a material of the protective film, a material containing ruthenium (Ru) is widely used as a material in which an etching rate of a dry etching using a halogen gas such as a chlorine-based gas an etching gas is slower than that of the absorption layer and which is less likely to be damaged by the dry etching.
Patent Literature 1: Japanese Patent No. 6343690
Patent Literature 2: Japanese Patent No. 3366572

### SUMMARY OF INVENTION

In recent years, while miniaturization and high densification of a pattern are in progress, a pattern with a higher resolution has been required. In order to obtain a pattern with a high resolution, it is necessary to reduce a film thickness of a resist. However, when the film thickness of the resist is reduced, the accuracy of a pattern to be transferred to the absorption layer may decrease due to consumption of a resist film during the etching process.

It is known that the resist can be thinned by providing, on the absorption layer, an etching mask film having resistance to etching conditions of the absorption layer (see Patent Literature 1).

In the EUV mask blank described in Patent Literature 1, a material containing chromium (Cr) is used for the etching mask film. In the EUV mask blank described in Patent Literature 1, dry etching is carried out using a mixed gas of a chlorine-based gas and an oxygen gas as an etching gas to remove an etching mask film including a material containing Cr.

The protective film including a material containing Ru is etched by a dry etching using a mixed gas of a chlorine-based gas and an oxygen gas as an etching gas (see Patent Literature 2).

Therefore, a protective film including a material containing Ru may be damaged by a dry etching using an oxygen-based gas such as a mixed gas of a chlorine-based gas and an oxygen gas as an etching gas.

A material containing Cr or ruthenium (Ru) may be used for the absorption layer. In this case, a transfer pattern is formed on the absorption layer by the dry etching using an oxygen-based gas as an etching gas. Therefore, the protective film including a material containing Ru may be damaged.

When the protective film is damaged by the etching process, the multilayer reflective film is also damaged. Damage to the multilayer reflective film leads to deterioration in optical characteristics of the EUV mask blank, such as decrease in reflectance of the multilayer reflective film.

In order to solve the above problems in the related art, an object of the present invention is to provide an EUV mask blank in which damage to a multilayer reflective film due to a dry etching using a halogen gas as an etching gas and a dry etching using an oxygen-based gas as an etching gas is prevented.

1. A reflective mask blank for EUV lithography, including, in the following order, a substrate, a multilayer reflective film reflecting EUV light, a protective film for the multilayer reflective film, and an absorption layer absorbing EUV light,
in which the protective film includes rhodium (Rh) or a rhodium material including Rh and at least one element selected from the group consisting of nitrogen (N), oxygen (O), carbon (C), boron (B), ruthenium (Ru), niobium (Nb), molybdenum (Mo), tantalum (Ta), iridium (Ir), palladium (Pd), zirconium (Zr), and titanium (Ti).

2. The reflective mask blank for EUV lithography according to the item 1, in which the protective film includes Rh and at least one element selected from the group consisting of N, O, C, and B.

3. The reflective mask blank for EUV lithography according to the item 2, in which the protective film includes Rh of 40 at % or more and 99 at % or less and the at least one element selected from the group consisting of N, O, C, and B of 1 at % or more and 60 at % or less.

4. The reflective mask blank for EUV lithography according to the item 1, in which the protective film includes Rh of 90 at % or more and has a film density of 10.0 g·cm⁻³ to 14.0 g·cm⁻³.

5. The reflective mask blank for EUV lithography according to any one of the items 1 to 4, in which the protective film includes at least one element (X) selected from the group consisting of Ru, Nb, Mo, Ta, Ir, Pd, Zr, and Ti in a composition ratio (at %) (Ru:X) of Rh and X of 99:1 to 1:1.

6. The reflective mask blank for EUV lithography according to any one of the items 1 to 5, in which the protective film has a film thickness of 1.0 nm or more and 10.0 nm or less.

7. The reflective mask blank for EUV lithography according to any one of the items 1 to 6, in which the protective film includes a surface having a surface roughness (rms) of 0.3 nm or less.

8. The reflective mask blank for EUV lithography according to any one of the items 1 to 7, further including a diffusion barrier layer between the multilayer reflective film and the protective film,
in which the diffusion barrier layer includes at least one element selected from Nb, Ru, Ta, silicon (Si), Zr, Ti, and Mo.

9. The reflective mask blank for EUV lithography according to the item 8, in which the diffusion barrier layer further includes at least one element selected from the group consisting of O, N, C, and B.

10. The reflective mask blank for EUV lithography according to any one of the items 1 to 9, in which the absorption layer includes at least one element selected from Ru, Ta, chromium (Cr), Nb, platinum (Pt), Ir, rhenium (Re), tungsten (W), manganese (Mn), gold (Au), Si, aluminum (Al), and hafnium (Hf).

11. The reflective mask blank for EUV lithography according to the item 10, in which the absorption layer further includes at least one element selected from the group consisting of O, N, C, and B.

12. The reflective mask blank for EUV lithography according to any one of the items 1 to 11, further including an etching mask film on the absorption layer,
in which the etching mask film includes at least one element selected from the group consisting of Cr, Nb, Ti, Mo, Ta, and Si.

13. The reflective mask blank for EUV lithography according to the item 12, in which the etching mask film further includes at least one element selected from the group consisting of O, N, C, and B.

14. A reflective mask for EUV lithography, including the reflective mask blank for EUV lithography according to any one of items 1 to 13 and a pattern formed on the absorption layer.

15. A method for manufacturing a reflective mask blank for EUV lithography, the method including:
forming a multilayer reflective film reflecting EUV light on or above a substrate;
forming a protective film on or above the multilayer reflective film; and
forming an absorption layer absorbing EUV light on or above the protective film,
in which the protective film includes Rh or a rhodium material including Rh and at least one element selected from the group consisting of N, O, C, B, Ru, Nb, Mo, Ta, Ir, Pd, Zr, and Ti.

16. A method for manufacturing a reflective mask for EUV lithography, the method including patterning an absorption layer of a reflective mask blank for EUV lithography manufactured by the method for manufacturing a reflective mask blank for EUV lithography according to the item 15 to form a pattern.

### Advantageous Effects of Invention

The EUV mask blank according to the present invention includes a protective film excellent in etching resistance against a dry etching using a halogen gas as an etching gas and a dry etching using an oxygen-based gas as an etching gas.

Therefore, the damage to the multilayer reflective film due to the dry etching using a halogen gas as an etching gas and the dry etching using an oxygen-based gas as an etching gas is prevented.

### BRIEF DESCRIPTION OF DRAWINGS

FIG. 1 is a schematic cross-sectional view illustrating an embodiment of an EUV mask blank according to the present invention.

FIG. 2 is a schematic cross-sectional view illustrating another embodiment of the EUV mask blank according to the present invention.

FIG. 3 is a schematic cross-sectional view illustrating further another embodiment of the EUV mask blank according to the present invention.

FIG. 4 is a schematic cross-sectional view illustrating an embodiment of an EUV mask according to the present invention.

FIG. 5 is a diagram showing a TEM observation result of a sample after a dry etching process using an oxygen-based gas in Example 1.

FIG. 6 is a diagram showing a TEM observation result of a sample after a dry etching process using an oxygen-based gas in Example 6.

### DESCRIPTION OF EMBODIMENTS

Hereinafter, an EUV mask blank according to the present invention will be described with reference to the drawings.

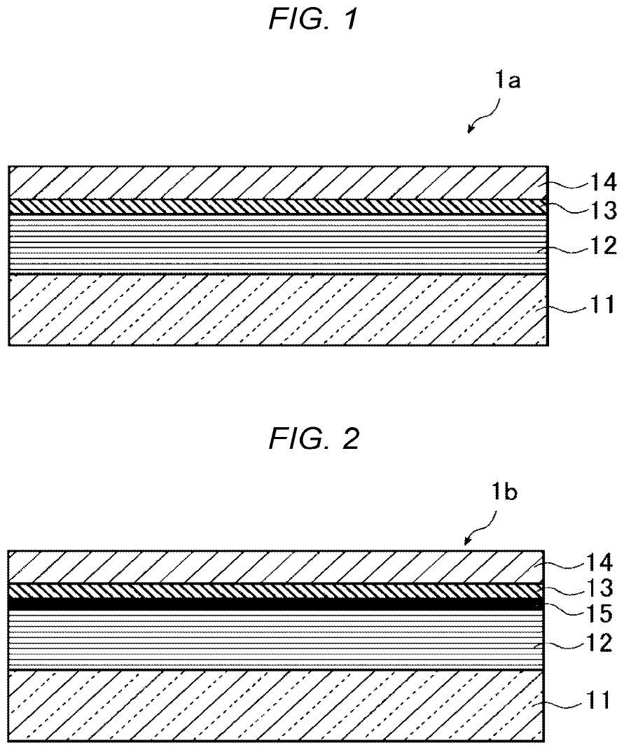

FIG. 1 is a schematic cross-sectional view illustrating an embodiment of the EUV mask blank according to the present invention. In an EUV mask blank 1a illustrated in FIG. 1, a multilayer reflective film 12 that reflects EUV light, a protective film 13 for the multilayer reflective film 12, and an absorption layer 14 that absorbs EUV light are formed in this order on or above a substrate 11.

Hereinafter, individual components of the EUV mask blank 1a will be described.

The substrate 11 satisfies characteristics as a substrate for an EUV mask blank. Therefore, the substrate 11 has a low coefficient of thermal expansion (specifically, the coefficient of thermal expansion at 20° C. is preferably 0+0.05×10⁻⁷/° C. and more preferably 0±0.03×10⁻⁷/° C.), and is excellent in smoothness, flatness, and resistance to a cleaning solution including an acid or a base. As the substrate 11, specifically, a glass having a low coefficient of thermal expansion, for example, an SiO₂—TiO₂ glass or the like is used, but without being limited thereto, for example, a crystallized glass in which a β-quartz solid solution is precipitated can also be used, a quartz glass, or a substrate of silicon, metal, or the like.

In the case where the substrate 11 has a smooth surface with a surface roughness (rms) of 0.15 nm or less and has a flatness of 100 nm or less, high reflectance and transfer accuracy can be obtained in a photomask after pattern formation. Therefore, the substrate 11 is preferable.

The size, the thickness, and the like of the substrate 11 are appropriately determined by design values and the like of the mask. In Examples to be described later, an SiO₂—TiO₂ glass having an outer shape of 6 inches (152 mm) square and a thickness of 0.25 inches (6.3 mm) is used.

It is preferable that no defect be present on a surface of the substrate 11 on which the multilayer reflective film 12 is formed. However, even in the case where a defect is present, there are no problems as long as a phase defect does not occur due to a concave defect and/or a convex defect. Specifically, a depth of the concave defect and a height of the convex defect are preferably 2 nm or less, and full widths at half maximum of the concave defect and the convex defect are preferably 60 nm or less. The full width at half maximum of the concave defect refers to a width at a depth position of ½ of the depth of the concave defect. The full width at half maximum of the convex defect refers to a width at a height position of ½ of the height of the convex defect.

The multilayer reflective film 12 achieves a high EUV light reflectance by alternately laminating a high refractive index layer and a low refractive index layer a plurality of times. In the multilayer reflective film 12, Mo is widely used for the high refractive index layer, and Si is widely used for the low refractive index layer. That is, an Mo/Si multilayer reflective film is most common. However, the multilayer reflective film is not limited thereto, and for example, an Ru/Si multilayer reflective film, an Mo/Be multilayer reflective film, an Mo compound/Si compound multilayer reflective film, an Si/Mo/Ru multilayer reflective film, an Si/Mo/Ru/Mo multilayer reflective film, or an Si/Ru/Mo/Ru multilayer reflective film may be used.

The multilayer reflective film 12 is not particularly limited as long as it has desired characteristics as a multilayer reflective film of a reflective mask blank. Here, the characteristic particularly required for the multilayer reflective film 12 is a high EUV light reflectance. Specifically, when the surface of the multilayer reflective film 12 is irradiated with light in a wavelength region of EUV light at an incident angle of 6°, the maximum value of the light reflectance at a wavelength of 13.5 nm is preferably 60% or more, and more preferably 65% or more.

A thickness of each of the layers constituting the multilayer reflective film 12 and the number of repeating units of the layer can be appropriately selected according to a film material to be used and the EUV light reflectance required for the multilayer reflective film. Taking the Mo/Si multilayer reflective film as an example, in order to obtain the multilayer reflective film 12 in which the maximum value of the EUV light reflectance is 60% or more, the multilayer reflective film may be formed by laminating an Mo layer having a film thickness of 2.3 nm±0.1 nm and an Si layer having a film thickness of 4.5 nm±0.1 nm so that the number of repeating units becomes 30 or more and 60 or less.

Each of the layers constituting the multilayer reflective film 12 may be formed to have a desired thickness using a known film forming method such as a magnetron sputtering method or an ion beam sputtering method. For example, in the case where an Si/Mo multilayer reflective film is formed using the ion beam sputtering method, it is preferable that an Si film is formed to have a thickness of 4.5 nm at an ion accelerating voltage of 300 V or more and 1,500 V or less and a film formation rate of 0.030 nm/sec or more and 0.300 nm/sec or less using an Si target as a target and using an Ar gas (gas pressure: 1.3×10⁻² Pa or more and 2.7×10⁻² Pa or less) as a sputtering gas, and an Mo film is formed to have a thickness of 2.3 nm at an ion accelerating voltage of 300 V and more and 1,500 V or less and a film formation rate of 0.030 nm/sec or more and 0.300 nm/sec or less using an Mo target as a target and using an Ar gas (gas pressure: 1.3×10⁻² Pa or more and 2.7×10⁻² Pa or less) as a sputtering gas. The Si/Mo multilayer reflective film is formed by laminating the Si film and the Mo film for 40 cycles or more and 50 cycles or less with the above as 1 cycle.

In order to prevent oxidation of the surface of the multilayer reflective film 12, it is preferable that the uppermost layer of the multilayer reflective film 12 be a layer of a material which is hardly oxidized. The layer of a material which is hardly oxidized functions as a cap layer for the multilayer reflective film 12. Specific examples of the layer of a material which is hardly oxidized, the layer functioning as a cap layer, include an Si layer. In the case where the multilayer reflective film 12 is an Si/Mo film, the uppermost layer functions as a cap layer by using the Si layer as the uppermost layer. In this case, a thickness of the cap layer is preferably 11 nm±2 nm.

The protective film 13 according to the present invention includes rhodium (Rh) or a rhodium material containing Rh and at least one element selected from the group consisting of nitrogen (N), oxygen (O), carbon (C), boron (B), ruthenium (Ru), niobium (Nb), molybdenum (Mo), tantalum (Ta), iridium (Ir), palladium (Pd), zirconium (Zr), and titanium (Ti). The protective film including Rh or the rhodium material has a low etching rate in the case where either a dry etching using a halogen gas as an etching gas (hereinafter, referred to as “dry etching with a halogen gas”) or a dry etching using an oxygen-based gas as an etching gas (hereinafter, referred to as “dry etching with an oxygen-based gas”) is carried out. Therefore, it exhibits excellent resistance to both the dry etching with a halogen gas widely used in patterning the absorption layer 14, and the dry etching with an oxygen-based gas used in removal of the etching mask film or patterning the absorption layer 14 using a ruthenium (Ru) material to be described later.

The dry etching with a halogen gas refers to a dry etching using a chlorine-based gas such as Cl₂, SiCl₄, CHCl₃, CCl₄ or BCl₃ and a mixed gas thereof as well as a dry etching using a fluorine-based gas such as CF₄, CHF₃, SF₆, BF₃ or XeF₂ and a mixed gas thereof.

The dry etching with an oxygen-based gas refers to a dry etching using an oxygen gas and a dry etching using a mixed gas of an oxygen gas and a halogen gas. As the halogen gas, the chlorine-based gas and a mixed gas thereof as well as the fluorine-based gas and a mixed gas thereof are used.

The resistance of the protective film 13 to the dry etching with a halogen gas and the resistance of the protective film 13 to the dry etching with an oxygen-based gas can be evaluated by an etching selectivity to the absorption layer 14 obtained by the following equation.

Etching selectivity=Etching rate of protective film 13/Etching rate of absorption layer 14

It is preferable that the etching selectivity of the protective film 13 to the absorption layer 14 be ⅕ or less in both the dry etching with a halogen gas and the dry etching with an oxygen-based gas.

The protective film 13 is required to have resistance to sulfuric acid-hydrogen peroxide mixture (SPM) used as a cleaning solution for a resist in EUV lithography. The protective film including Rh or the rhodium material is excellent in resistance to SPM.

The EUV mask blank is required to achieve a high EUV light reflectance even in the case where the protective film 13 is provided on the multilayer reflective film 12. Specifically, even in the state where the protective film 13 is provided on the multilayer reflective film 12, the maximum value of the light reflectance in the vicinity of a wavelength of 13.5 nm is preferably 60% or more, and more preferably 65% or more. The protective film including Rh or the rhodium material has a low refractive index and a low extinction coefficient in a wavelength region of EUV light. Therefore, the EUV light reflectance can be achieved.

The protective film 13 including Rh is particularly excellent in resistance to the dry etching with a halogen gas and the dry etching with an oxygen-based gas.

The protective film 13 including a rhodium material containing Rh and at least one element (X) selected from the group consisting of Ru, Nb, Mo, Ta, Ir, Pd, Zr, and Ti is an alloy film of Rh and the element X. The alloy film of Rh and the element X has a lower resistance to the dry etching with a halogen gas and the dry etching with an oxygen-based gas than the protective film including Rh, but has an improved EUV light reflectance in the state where the protective film 13 is provided on the multilayer reflective film 12. Ru, Nb, Mo, and Zr are preferable as the element X because the EUV light reflectance in the state where the protective film 13 is provided on the multilayer reflective film 12 is improved.

The alloy film of Rh and the element X preferably contains Rh and the element X at a composition ratio (at %) (Ru:X) of Rh and X of 99:1 to 1:1. In the case where X in the composition ratio (at %) of Rh and X is more than 99:1, the EUV light reflectance in the state where the protective film 13 is provided on the multilayer reflective film 12 is improved. In the case where X in the composition ratio (at %) of Rh and X is less than 1:1, the resistance to the dry etching with a halogen gas and the dry etching with an oxygen-based gas is excellent. The alloy film of Rh and the element X preferably contains Rh and the element X in a composition ratio (at %) (Ru:X) of Rh and X in a range of 10:3 to 1:1.

In the case of performing the dry etching using a mixed gas of an oxygen gas and a halogen gas as the dry etching with an oxygen-based gas, the etching rate of the protective film including Rh or the Rh material does not greatly change even in the case where a mixing ratio of the oxygen gas and the halogen gas is changed. Therefore, by adjusting the mixing ratio of the oxygen gas and the halogen gas so as to maximize the etching rate of the absorption layer 14, the etching selectivity to the absorption layer 14 can be reduced.

The protective film 13 according to the present invention may contain at least one element Y selected from the group consisting of N, O, C, and B in addition to Rh or Rh and the element X. In the case where the element Y is contained, the resistance to the dry etching with a halogen gas and the dry etching with an oxygen-based gas decreases, but the crystallinity of the film decreases, and a crystalline state of the film becomes an amorphous structure or a microcrystalline structure. Accordingly, the smoothness of the protective film is improved. Whether the crystalline state of the film is the amorphous structure or the microcrystalline structure can be confirmed by an X-ray diffraction (XRD) method. In the case where the crystalline state of the film is the amorphous structure or the microcrystalline structure, no sharp peak is observed in a diffraction peak obtained by XRD measurement.

In the case where at least one element selected from the group consisting of N, O, C, and B is contained as the element Y, it is preferable that Rh or a total of Rh and the element X be contained in an amount of 40 at % or more and 99 at % or less and at least one element selected from the group consisting of N, O, C, and B is contained in a total of 1 at % or more and 60 at % or less, and it is more preferable that Rh or the total of Rh and the element X is contained in an amount of 80 at % or more and 99 at % or less and at least one element selected from the group consisting of N, O, C, and B is contained in a total of 1 at % or more and 20 at % or less.

In the case where the protective film 13 contains 90 at % or more of Rh and the film density is 10.0 g·cm⁻³ to 14.0 g·cm⁻³, the crystallinity of the film is low, and the crystalline state of the film is an amorphous structure or a microcrystalline structure. Accordingly, the smoothness of the protective film is improved. In this case, the protective film 13 contains the element X and/or the element Y in addition to Rh. The film density of the protective film 13 is preferably 11.0 g·cm⁻³ to 13.0 g·cm⁻³. In the case where the protective film 13 contains 100 at % of Rh, that is, in the case where the protective film 13 is consisting of Rh, as long as the film density is in a range of 11.0 g·cm⁻³ to 12.0 g·cm⁻³, the crystallinity of the film is low, and the crystalline state of the film is an amorphous structure or a microcrystalline structure. Accordingly, the smoothness is improved.

The film density of the protective film 13 was measured using the X-ray reflectometry in Examples to be described later, but is not limited thereto, for example, it is also possible to calculate the density by a ratio of a surface density measured by Rutherford backscattering spectroscopy to a film thickness measured by a transmission electron microscope.

The film thickness of the protective film 13 is preferably 1.0 nm or more and 10.0 nm or less, and more preferably 2.0 nm or more and 3.5 nm or less.

The protective film 13 preferably has an excellent surface smoothness. In the case where the protective film 13 has an excellent surface smoothness, the surface smoothness of the absorption layer 14 formed on the protective film 13 is improved. The surface roughness (rms) of the surface of the protective film is preferably 0.3 nm or less, and more preferably 0.1 nm or less. The surface roughness (rms) of the surface of the protective film is preferably 0.001 nm or more, and more preferably 0.01 nm or more.

The protective film 13 is formed using a known film forming method such as a magnetron sputtering method or an ion beam sputtering method. For example, in the case where a Rh film is formed using a DC sputtering method, it is preferable to form the film by using a Rh target as a target and using an Ar gas (gas pressure: 1.0×10⁻² Pa or more and 1.0×10⁰ Pa or less) as a sputtering gas so that the supplied power density per target area is 1.0 W/cm² or more and 8.5 W/cm² or less, the film formation rate is 0.020 nm/sec or more and 1.000 nm/sec or less, and the thickness is 1 nm or more and 10 nm or less. In the case where a Rh film is formed, an N₂ gas or a mixed gas of an Ar gas and N₂ (volume ratio (N₂/(Ar+N₂)) of N₂ gas in mixed gas=0.05 or more and 1.0 or less), and gas pressure of 1.0×10⁻² Pa or more and 1.0×10⁰ Pa or less) may be used as the sputtering gas.

In the case where an RhO film is formed using the DC sputtering method, it is preferable to form the RhO film by using a Rh target as a target and using an O₂ gas or a mixed gas of an Ar gas and O₂ (volume ratio (O₂/(Ar+O₂)) of O₂ gas in mixed gas=0.05 or more and 1.0 or less), and gas pressure of 1.0×10⁻² Pa or more and 1.0×10⁰ Pa or less) as a sputtering gas so that the supplied power density per target area is 1.0 W/cm² or more and 8.5 W/cm² or less, the film formation rate is 0.020 nm/sec or more and 1.000 nm/sec or less, and the thickness is 1 nm or more and 10 nm or less. In the case where an RhRu film is formed using the DC sputtering method, it is preferable to form the RhRu film by using a Rh target and a Ru target as targets or by using an RhRu target as a target and using an Ar gas (gas pressure of 1.0×10⁻² Pa or more and 1.0×10⁰ Pa or less) as a sputtering gas so that the supplied power density per target area is 1.0 W/cm² or more and 8.5 W/cm² or less, the film formation rate is 0.020 nm/sec or more and 1.000 nm/sec or less, and the thickness is 1 nm or more and 10 nm or less.

The absorption layer 14 preferably contains at least one element selected from Ru, Ta, chromium (Cr), Nb, platinum (Pt), Ir, rhenium (Re), tungsten (W), manganese (Mn), gold (Au), Si, aluminum (Al), and hafnium (Hf).

In the case of the absorption layer 14 for a binary mask, the absorption layer 14 preferably contains at least one element selected from Ta, Nb, Pt, Ir, Re, and Cr, more preferably contains at least one element selected from Ta and Nb, and still more preferably contains Ta. In the case where the absorption layer 14 contains at least one of Ta and Nb, it is preferable to form a transfer pattern by the dry etching with a halogen gas, and it is more preferable to perform the dry etching using a chlorine-based gas as the dry etching with a halogen gas. In the case where the absorption layer 14 contains at least one of Pt and Ir, it is preferable to form a transfer pattern by the dry etching with a halogen gas, and a fluorine-based gas is preferably used as the halogen gas. In the case where the absorption layer 14 contains at least one of Cr and Re, it is preferable to form a transfer pattern by the dry etching with an oxygen-based gas, and it is more preferable to perform the dry etching using a mixed gas of an oxygen gas and a chlorine-based gas as the dry etching with an oxygen-based gas.

In the case of the absorption layer 14 for a phase shift mask, the absorption layer 14 preferably contains Ru, and more preferably contains at least one element selected from Ta, Cr, Ir, Re, W, and Hf. In the case where Ru and the above element are contained, Ru and the element form an alloy. In the case of a Ru alloy containing Ru and at least one element selected from Ta, Cr, Ir, Re, W, and Hf, the EUV light reflectance can be controlled by the content of the above element with respect to Ru, and thus the content of the above element can be adjusted so as to achieve a desired EUV light reflectance. On the other hand, in the case where the content of the above element with respect to Ru is too large, the refractive index n in the wavelength region of EUV light becomes large, and the film thickness necessary for reversing a phase becomes thick, and thus the content of the above element with respect to Ru is preferably 50 at % or less. In the case where the Ru alloy contains two or more of the above elements, the content of the above element refers to a total content of the two or more elements.

In the case where the absorption layer 14 contains Ru or a Ru alloy containing Ru and at least one element selected from Ta, Cr, Ir, Re, W, and Hf, it is preferable to form a transfer pattern by the dry etching with an oxygen-based gas, and it is more preferable to perform the dry etching using a mixed gas of an oxygen gas and a halogen gas as the dry etching with an oxygen-based gas. The etching rate of the absorption layer 14 can be adjusted by the mixing ratio of the oxygen gas and the halogen gas in the oxygen-based gas. The mixing ratio of the oxygen gas and the halogen gas is such that a volume ratio (oxygen gas:halogen gas) of the oxygen gas to the halogen gas is preferably 10:90 to 50:50, and more preferably 20:80 to 40:60. In the case where the Ru alloy contains at least one element selected from Ta, Cr, Ir, and W, it is preferable to use a fluorine-based gas as the halogen gas.

In both cases of the absorption layer 14 for a binary mask and the absorption layer 14 for a phase shift mask, the absorption layer 14 may contain at least one element selected from the group consisting of O, N, C, and B in addition to the above elements. By containing these elements, the crystallinity of the film is lowered, and the surface smoothness of the absorption layer is improved. It is more preferable to contain at least one element selected from the group consisting of O, N, and B, and it is still more preferable to contain at least one element selected from the group consisting of O and N.

Examples of the absorption layer 14 for the binary mask include a TaN film containing Ta and N. Examples of the absorption layer 14 for the phase shift mask include an RuON film containing Ru, O, and N.

In both cases of the absorption layer 14 for the binary mask and the absorption layer 14 for the phase shift mask, the film thickness of the absorption layer 14 is preferably 20 nm or more and 80 nm or less, more preferably 30 nm or more and 70 nm or less, and still more preferably 40 nm or more and 60 nm or less.

In both cases of the absorption layer 14 for the binary mask and the absorption layer 14 for the phase shift mask, a film is formed using a known film forming method such as a magnetron sputtering method or an ion beam sputtering method.

For example, in the case where the TaN film is formed using the magnetron sputtering method, it is preferable to form the film by using a Ta target as a target and using a mixed gas of Ar and N₂ (gas pressure: 1.0×10⁻¹ Pa or more and 50×10⁻¹ Pa or less) as a sputtering gas so that the supplied power density is 1.0 W/cm² or more and 8.5 W/cm² or less, the film formation rate is 0.020 nm/sec or more and 1.000 nm/sec or less, and the thickness is 20 nm or more and 80 nm or less.

In the case where the RuON film is formed using the magnetron sputtering method, it is preferable to form the film by using a Ru target as a target and using a mixed gas of Ar, O₂, and N₂ (gas pressure: 1.0×10⁻² Pa or more and 1.0×10⁰ Pa or less) as a sputtering gas so that the supplied power density is 1.0 W/cm² or more and 8.5 W/cm² or less, the film formation rate is 0.020 nm/sec or more and 1.000 nm/sec or less, and the thickness is 20 nm or more and 80 nm or less.

In the case where an RuN film is formed using the magnetron sputtering method, it is preferable to form the film by using a Ru target as a target and using a mixed gas of Ar and N₂ (gas pressure: 1.0×10⁻² Pa or more and 1.0×10⁰ Pa or less) as a sputtering gas so that the supplied power density is 1.0 W/cm² or more and 8.5 W/cm² or less, the film formation rate is 0.020 nm/sec or more and 1.000 nm/sec or less, and the thickness is 20 nm or more and 80 nm or less.

In the case where an RuB film is formed using the magnetron sputtering method, it is preferable to form the film by using a Ru target and a B target as targets or by using an RuB compound target as a target and using an Ar gas (gas pressure: 1.0×10⁻² Pa or more and 1.0×10⁰ Pa or less) as a sputtering gas so that the supplied power density is 0.1 W/cm² or more and 8.5 W/cm² or less, the film formation rate is 0.010 nm/sec or more and 1.000 nm/sec or less, and the thickness is 20 nm or more and 80 nm or less.

In the case where an RuTa film is formed using the magnetron sputtering method, it is preferable to form the film by using a Ru target and a Ta target as targets or by using an RuTa compound target as a target and using an Ar gas (gas pressure: 1.0×10⁻² Pa or more and 1.0×10⁰ Pa or less) as a sputtering gas so that the supplied power density is 0.1 W/cm² or more and 8.5 W/cm² or less, the film formation rate is 0.020 nm/sec or more and 1.000 nm/sec or less, and the thickness is 20 nm or more and 80 nm or less.

In the case where an RuW film is formed using the magnetron sputtering method, it is preferable to form the film by using a Ru target and a W target as targets or by using an RuW compound target as a target and using an Ar gas (gas pressure: 1.0×10⁻² Pa or more and 1.0×10⁰ Pa or less) as a sputtering gas so that the supplied power density is 0.1 W/cm² or more and 8.5 W/cm² or less, the film formation rate is 0.020 nm/sec or more and 1.000 nm/sec or less, and the thickness is 20 nm or more and 80 nm or less.

In the case where an RuCr film is formed using the magnetron sputtering method, it is preferable to form the film by using a Ru target and a Cr target as targets or by using an RuCr compound target as a target and using an Ar gas (gas pressure: 1.0×10⁻² Pa or more and 1.0×10⁰ Pa or less) as a sputtering gas so that the supplied power density is 0.1 W/cm² or more and 8.5 W/cm² or less, the film formation rate is 0.020 nm/sec or more and 1.000 nm/sec or less, and the thickness is 20 nm or more and 80 nm or less.

The absorption layer containing Ta suitable for the absorption layer 14 for the binary mask can form a transfer pattern by the dry etching with a halogen gas.

The absorption layer containing Ru suitable as the absorption layer 14 for the phase shift mask can form a transfer pattern by the dry etching with an oxygen-based gas.

FIG. 2 is a schematic cross-sectional view illustrating another embodiment of the EUV mask blank according to the present invention. In an EUV mask blank 1b illustrated in FIG. 2, the multilayer reflective film 12, a diffusion barrier layer 15, the protective film 13, and the absorption layer 14 are formed in this order on or above the substrate 11.

Among the components of the EUV mask blank 1b, the substrate 11, the multilayer reflective film 12, the protective film 13, and the absorption layer 14 are the same as those of the above EUV mask blank 1a, and thus the description thereof will be omitted.

In the case where Rh or the rhodium material of the protective film 13 diffuses into the uppermost layer (Si layer) of the multilayer reflective film 12, the EUV reflectance may decrease. By providing the diffusion barrier layer 15, it is possible to prevent Rh or the rhodium material of the protective film 13 from diffusing into the uppermost layer (Si layer) of the multilayer reflective film 12.

The diffusion barrier layer 15 preferably contains at least one element selected from Nb, Ru, Ta, Si, Zr, Ti, and Mo, and more preferably contains at least one element selected from Nb, Si, and Ru.

The diffusion barrier layer 15 may contain at least one element selected from the group consisting of O, N, C, and B in addition to the above elements. By containing these elements, the film thickness of the diffusion barrier layer 15 necessary to prevent diffusion from the protective film 13 to the multilayer reflective film 12 can be reduced. It is more preferable to contain at least one element selected from the group consisting of O, N, and B, and it is still more preferable to contain at least one element selected from the group consisting of O and N.

The diffusion barrier layer 15 preferably has a film thickness of 0.5 nm or more and 2.0 nm or less, more preferably 0.5 nm or more and 1.0 nm or less.

The diffusion barrier layer 15 is formed by a known film forming method such as a magnetron sputtering method or an ion beam sputtering method. In the case where a Ru film is formed by the magnetron sputtering method, it is preferable to form the Ru film by using a Ru target as a target and using an Ar gas (gas pressure: 1.0×10² Pa or more and 1.0×10⁰ Pa or less) as a sputtering gas so that the supplied voltage is 30 V or more and 1,500 V or less, the film formation rate is 0.020 nm/sec or more and 1.000 nm/sec or less, and the thickness is 0.1 nm or more and 2 nm or less.

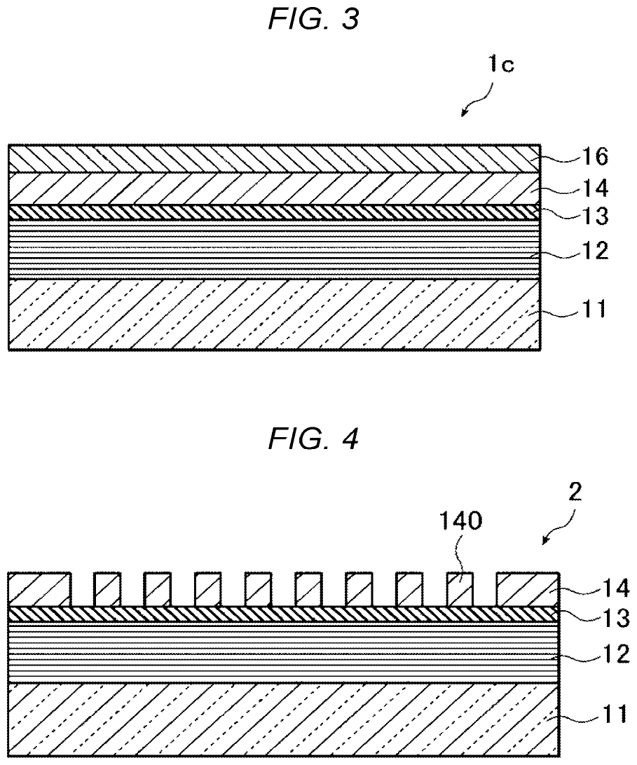

FIG. 3 is a schematic cross-sectional view illustrating still another embodiment of the EUV mask blank according to the present invention. In an EUV mask blank 1c illustrated in FIG. 3, the multilayer reflective film 12, the protective film 13, the absorption layer 14, and an etching mask film 16 are formed in this order on or above the substrate 11.

Among the components of the EUV mask blank 1c, the substrate 11, the multilayer reflective film 12, the protective film 13, and the absorption layer 14 are the same as those of the EUV mask blank 1a described above, and the description thereof is omitted.

In the EUV mask blank 1c illustrated in FIG. 3, the resist can be thinned by providing the etching mask film 16 on the absorption layer 14.

The etching mask film 16 preferably contains at least one element selected from the group consisting of Cr, Nb, Ti, Mo, Ta, and Si.

In the case of the absorption layer containing Ta suitable for the absorption layer 14 for the binary mask, the etching mask film 16 preferably contains Cr.

In the case of the absorption layer containing Ru suitable for the absorption layer 14 for the phase shift mask, the etching mask film 16 preferably contains Nb.

The etching mask film 16 may contain at least one element selected from the group consisting of O, N, C, and B in addition to the above elements. It is more preferable to contain at least one element selected from the group consisting of O, N, and B, and it is still more preferable to contain at least one element selected from the group consisting of O and N.

The film thickness of the etching mask film 16 is preferably 2 nm or more and 30 nm or less, more preferably 2 nm or more and 25 nm or less, and still more preferably 2 nm or more and 10 nm or less.

The etching mask film 16 can be formed by a known film forming method, for example, a magnetron sputtering method or an ion beam sputtering method.

The EUV mask blanks 1a to 1c according to the present invention may include a functional film known in the field of EUV mask blanks in addition to the multilayer reflective film 12, the protective film 13, the diffusion barrier layer 15, the absorption layer 14, and the etching mask film 16. Specific examples of such a functional film include a high dielectric coating applied to a rear surface side of a substrate in order to promote static chucking of the substrate as described in JP2003-501823A. Here, the rear surface of the substrate refers to a surface of the substrate 11 in FIG. 1 opposite to a side on which the multilayer reflective film 12 is formed. For the high dielectric coating applied to the rear surface of the substrate for such a purpose, an electrical conductivity and a thickness of the constituent material are selected so that a sheet resistance is 100 Ω/square or less. The constituent material of the high dielectric coating can be widely selected from those described in known documents. For example, a coating having a high dielectric constant, specifically, a coating made of silicon, TiN, molybdenum, chromium, or TaSi, as described in JP2003-501823A, can be applied. A thickness of the high dielectric coating may be, for example, 10 nm or more and 1,000 nm or less.

The high dielectric coating can be formed by a known film forming method, for example, a sputtering method such as a magnetron sputtering method or an ion beam sputtering method, a CVD method, a vacuum deposition method, or an electrolytic plating method.

A method for manufacturing an EUV mask blank according to the present invention includes the following steps a) to c):
a) forming a multilayer reflective film that reflects EUV light on or above a substrate;
b) forming a protective film including Rh or a rhodium material on or above the multilayer reflective film formed in the step a); and
c) forming an absorption layer that absorbs EUV light on or above the protective film formed in the step b).

According to the method for manufacturing an EUV mask blank according to the present invention, the EUV mask blank 1a illustrated in FIG. 1 is obtained.

FIG. 4 is a schematic cross-sectional view illustrating an embodiment of the EUV mask according to the present invention. In an EUV mask 2 illustrated in FIG. 4, patterns (absorption layer patterns) 140 are formed on the absorption layer 14 of the EUV mask blank 1a illustrated in FIG. 1. That is, the multilayer reflective film 12 that reflects EUV light, the protective film 13 for the multilayer reflective film 12, and the absorption layer 14 that absorbs EUV light are formed in this order on or above the substrate 11, and the patterns (absorption layer patterns) 140 are formed on the absorption layer 14.

Among the components of the EUV mask blank 2, the substrate 11, the multilayer reflective film 12, the protective film 13, and the absorption layer 14 are the same as those of the EUV mask blank 1a described above.

In the method for manufacturing an EUV mask according to the present invention, the method including patterning the absorption layer 14 of the EUV mask blank manufactured by the method for manufacturing an EUV mask blank according to the present invention to form a pattern. In the EUV mask blank according to the present invention, since the protective film 13 is excellent in resistance to the dry etching with a halogen gas and the dry etching with an oxygen-based gas, damage to the multilayer reflective film 12 during patterning of the absorption layer 14 can be prevented.

### EXAMPLES

The present invention will be described in more detail below using Examples, but the present invention is not limited to Examples. Among Examples 1 to 19, Examples 1 to 5 and Examples 8 to 19 are inventive example, and Examples 6 and 7 are comparative examples.

### Example 1

In Example 1, the EUV mask blank illustrated in FIG. 1 was prepared.

As a substrate for film formation, an SiO₂—TiO₂ glass substrate (outer shape: 6 inches (152 mm) square, thickness: 6.3 mm) was used. The glass substrate had a coefficient of thermal expansion at 20° C. of 0.02×10⁻⁷/° C., a Young's modulus of 67 GPa, a Poisson's ratio of 0.17, and a specific stiffness of 3.07×10⁷ m²/s². This glass substrate was polished to form a smooth surface having a surface roughness (rms) of 0.15 nm or less and a flatness of 100 nm or less.

On a rear surface side of the substrate, a Cr film having a thickness of 100 nm was formed using a magnetron sputtering method, thereby applying a high dielectric coating having a sheet resistance of 100 Ω/square.

The Si/Mo multilayer reflective film 12 having a total film thickness of 272 nm ((4.5 nm+2.3 nm)×40) was formed by fixing the substrate (outer shape: 6 inches (152 mm) square, thickness: 6.3 mm) to a general electrostatic chuck having a flat plate shape via the formed Cr film, and repeating 40 cycles of alternately forming an Si film and an Mo film on the surface of the substrate using an ion beam sputtering method.

Further, a protective film was formed by forming a Rh film (film thickness: 2.5 nm) on the Si/Mo multilayer reflective film using a DC sputtering method. The EUV light reflectance after the formation of the protective film was 64.5% at maximum.

Film formation conditions of the Si film, the Mo film and the Rh film are as follows.

<Si Film Formation Conditions>
Target: Si target (boron doped)
Sputtering gas: Ar gas (gas pressure: 2.0×10⁻² Pa)
Voltage: 700 V
Film formation rate: 0.077 nm/sec
Film thickness: 4.5 nm

<Mo Film Formation Conditions>
Target: Mo target
Sputtering gas: Ar gas (gas pressure: 2.0×10⁻² Pa)
Voltage: 700 V
Film formation rate: 0.064 nm/sec
Film thickness: 2.3 nm

<Rh Film Formation Conditions>
Target: Rh target
Sputtering gas: Ar gas (gas pressure: 2.0×10⁻² Pa)
Supplied power density per target area: 3.7 W/cm²
Film formation rate: 0.048 nm/sec

Next, an absorption layer (RuON film) containing RuON, an absorption layer (RuN film) containing RuN, or an absorption layer (TaN film) containing TaN was formed on the protective film by a reactive sputtering method as the magnetron sputtering method. Film formation conditions of the absorption layer (RuON film) containing RuON, the absorption layer (RuN film) containing RuN, and the absorption layer (TaN film) containing TaN are as follows.

<RuON Film Formation Conditions>
Target: Ru target
Sputtering gas: mixed gas of Ar gas, O₂, and N₂ (volume ratio (O₂/(Ar+O₂+N₂)) of O₂
gas in mixed gas=0.17, volume ratio (N₂/(Ar+O₂+N₂)) of N₂ gas in mixed gas=0.17, gas pressure: 2.0×0⁻¹ Pa)
Supplied power density per target area: 7.4 W/cm²
Film formation rate: 0.20 nm/sec
The composition ratio (at %) of RuON is Ru:O:N=40:55:5.
Film thickness: 52 nm

<RuN Film Formation Conditions>
Target: Ru target
Sputtering gas: mixed gas of Ar gas and N₂ (volume ratio (N₂/(Ar+N₂)) of N₂ gas in mixed gas=0.17, gas pressure: 2.0×10⁻¹ Pa)
Supplied power density per target area: 6.2 W/cm²
Film formation rate: 0.20 nm/sec
The composition ratio (at %) of RuN is Ru:N=98:2.
Film thickness: 35 nm

<TaN Film Formation Conditions>
Target: Ta target
Sputtering gas: mixed gas of Ar gas and N₂ (volume ratio (N₂/(Ar+N₂)) of N₂ gas in mixed gas=0.17, gas pressure: 2.0×10⁻¹ Pa)
Supplied power density per target area: 4.3 W/cm²
Film formation rate: 0.029 nm/sec
Film thickness: 60 nm
   Or, an absorption layer (RuB film) containing RuB was formed on the protective film by the magnetron sputtering method. The film formation conditions of the absorption layer (RuB film) containing RuB are as follows.

<RuB Film Formation Conditions>
Target: Ru target
   B target
Sputtering gas: Ar gas (gas pressure: 2.0×10⁻¹ Pa)
Supplied power density per Ru target area: 0.2 W/cm²
Supplied power density per B target area: 10.0 W/cm²
Film formation rate: 0.013 nm/sec
The composition ratio (at %) of RuB is Ru:B=80:20.
Film thickness: 35 nm

The EUV mask blank obtained by the above procedures was subjected to the following etching resistance evaluations (1) to (3). In the following evaluations (1) to (3), similar evaluation results are obtained in the case where an absorption layer is not laminated on a protective film and the case where a Rh film is formed on a silicon wafer. The film composition in each example was analyzed using an X-ray photoelectron spectroscopy (manufactured by ULVAC-PHI, Inc.).

(1) Evaluation on Resistance to Dry Etching Using Mixed Gas of Oxygen Gas and Chlorine Gas as Oxygen-Based Gas

A sample on which a protective film (Rh film) was formed was placed on a sample stage of an ICP (inductively coupled) plasma etching apparatus, and an ICP plasma etching was performed under the following conditions to determine an etching rate. Further, a sample on which an absorption layer (RuON film, RuN film, or RuB film) containing RuON, RuN, or RuB was formed was placed, and the etching rate was obtained by the same procedure.
ICP antenna bias: 200 W
Substrate bias: 40 W
Trigger pressure: 3.5×10⁰ Pa
Etching pressure: 3.0×10⁻¹ Pa
Etching gas: mixed gas of O₂ and Cl₂
Gas flow rate (Cl₂/O₂): 10/10 sccm

The etching rate of the Rh protective film calculated by the etching was 0.4 nm/min. The etching rate of the absorption layer (RuON film, RuN film, or RuB film) containing RuON, RuN, or RuB was 45.8 nm/min, 18.3 nm/min, and 12.3 nm/min, respectively. The etching selectivity of the Rh protective film to the absorption layer (RuON film, RuN film, or RuB film) containing RuON, RuN, or RuB is 8.7×10⁻³, 2.2×10⁻², or 3.3×10⁻², respectively, which is sufficiently low to the etching rate of the corresponding absorption layer (RuON film, RuN film, or RuB film). Therefore, the protective film (Rh film) has sufficient resistance to the dry etching using a mixed gas of an oxygen gas and a chlorine-based gas as an oxygen-based gas.

A sample in which the Si/Mo multilayer reflective film and the Rh film were formed on the substrate by the above procedures was etched for 60 seconds under the same conditions as described above. For each of the samples before and after the etching, the composition of a surface of the sample was analyzed using an X-ray photoelectron spectroscopy (XPS). The composition before the etching was Rh:Si:Mo=81.4:17.3:1.3, and the composition of the sample after the etching was Rh:Si:Mo=81.0:18.4:0.6. There was little difference in the compositions of the samples before and after etching. The reason why Si and Mo are detected is that the XPS detects the Si film and the Mo film serving as the base of the Rh film because an optical resolution of the XPS in a depth direction is about several nm to 10 nm.

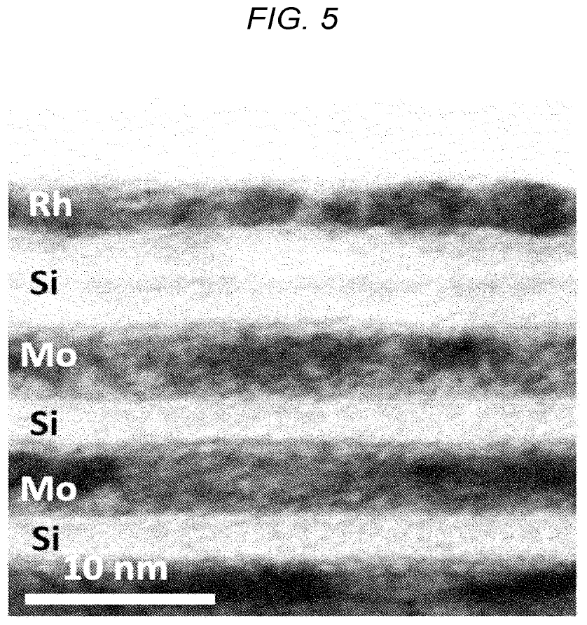

FIG. 5 shows a result of transmission electron microscope (TEM) observation on the sample after the etching. It was confirmed from a TEM image that the Rh protective film was also present after the etching.

(2) Evaluation on Resistance to Dry Etching Using Fluorine-Based Gas as Halogen Gas

Similar as (1), an ICP plasma etching was performed under the following conditions to determine the etching rate. A sample on which an absorption layer (TaN film) containing TaN was formed was placed, and the etching rate was obtained by the same procedures.
ICP antenna bias: 100 W
Substrate bias: 40 W
Trigger pressure: 3.5×10⁰ Pa
Etching pressure: 3.0×10⁻¹ Pa
Etching gas: mixed gas of He and CF₄
Gas flow rate (He/CF₄): 12/12 sccm

The etching rate of the Rh protective film calculated by the above etching was 1.4 nm/min. The etching rate of the absorption layer (TaN film) containing TaN was 22.1 nm/min. The etching selectivity of the Rh protective film to the absorption layer (TaN film) containing TaN is 0.063, which is sufficiently low to the etching rate of the absorption layer (TaN film). Therefore, the protective film (Rh film) has sufficient resistance to the dry etching using a fluorine-based gas as a halogen gas.

(3) Evaluation on SPM Resistance

A sample on which a protective film (Rh film) was formed was immersed in the following solution, and a change in film thickness before and after the treatment was examined.

Solution:concentrated sulfuric acid:hydrogen peroxide=3:1(volume ratio)Solution temperature:100° C.
Treatment time: 20 minutes

After the immersion treatment, the film thickness of the Rh film was increased by about 0.7 nm, and it was confirmed that there was no problem in the SPM resistance.

### Example 2

Example 2 was carried out in the same procedures as in Example 1 except that a Rh film (film thickness: 2.5 nm) was formed as a protective film under the following conditions.

<Rh Film Formation Conditions>
Target: Rh target
Sputtering gas: mixed gas of Ar gas and N₂ (volume ratio (N₂/(Ar+N₂)) of N₂ gas in mixed gas=0.31, gas pressure: 1.5×10⁻¹ Pa)
Supplied power density per target area: 3.7 W/cm²
Film formation rate: 0.037 nm/sec

A protective film (Rh film) as a sample was formed on a sample stage (4-inch quartz substrate) under the same conditions as described above. The film density of the sample was measured using X-ray reflectometry (XRR). The film density of the Rh film was 11.9 g·cm⁻³. The sample was subjected to XRD measurement. No sharp peak was observed in an obtained diffraction peak, and it was confirmed that the crystalline state of the film was an amorphous structure or a microcrystalline structure.

The etching rate of the dry etching using a mixed gas of an oxygen gas and a chlorine gas as an oxygen-based gas was 0.77 nm/min, and the etching rate of the dry etching using a fluorine-based gas as a halogen gas was 2.7 nm/min. The etching selectivity to the absorption layer containing RuON and the etching selectivity to the absorption layer containing TaN were 0.017 and 0.12, respectively, which were sufficiently low to the etching rates of the respective absorption layers. Therefore, the protective film (Rh film) has sufficient resistance to the dry etching using a mixed gas of an oxygen gas and a chlorine gas as an oxygen-based gas and the dry etching using a fluorine-based gas as a halogen gas.

### Example 3

Example 3 was carried out in the same procedures as in Example 1 except that an RhRu film (film thickness: 2.5 nm) was formed as a protective film under the following conditions.

<RhRu Film Formation Conditions>
Target: Rh target
Ru target
Sputtering gas: Ar gas (gas pressure: 2.0×10⁻¹ Pa)
Supplied power density per Rh target area: 3.7 W/cm²
Supplied power density per Ru target area: 1.5 W/cm²
Film formation rate: 0.58 nm/sec
The composition ratio (at %) of RhRu is Rh:Ru=75:25.

The etching rate of the dry etching using a mixed gas of an oxygen gas and a chlorine gas as an oxygen-based gas was 1.0 nm/min, and the etching rate of the dry etching using a fluorine-based gas as a halogen gas was 3.2 nm/min. The etching selectivity to the absorption layer (RuON film) containing RuON and the etching selectivity to the absorption layer (TaN film) containing TaN are 0.022 and 0.14, respectively, which are sufficiently low to the etching rates of the respective absorption layers (RuON film and TaN film). Therefore, the RhRu film has sufficient resistance to the dry etching using a mixed gas of an oxygen gas and a chlorine gas as an oxygen-based gas and the dry etching using a fluorine-based gas as a halogen gas.

### Example 4

Example 4 was carried out in the same procedures as in Example 1 except that an RhRu film (film thickness: 2.5 nm) was formed as a protective film under the following conditions.

<RhRu Film Formation Conditions>
Target: Rh target
   Ru target
Sputtering gas: Ar gas (gas pressure: 2.0×10⁻¹ Pa)
Supplied power density per Rh target area: 3.7 W/cm²
Supplied power density per Ru target area: 4.7 W/cm²
Film formation rate: 0.88 nm/sec
The composition ratio (at %) of RhRu is Rh:Ru=50:50.

The etching rate of the dry etching using a mixed gas of an oxygen gas and a chlorine gas as an oxygen-based gas was 1.2 nm/min, and the etching rate of the dry etching using a fluorine-based gas as a halogen gas was 3.7 nm/min. The etching selectivity to the absorption layer (RuON layer) containing RuON and the etching selectivity to the absorption layer (TaN film) containing TaN are 0.026 and 0.17, respectively, which are sufficiently low to the etching of the respective absorption layers (RuON film and TaN film). Therefore, the RhRu film has sufficient resistance to the dry etching using a mixed gas of an oxygen gas and a chlorine gas as an oxygen-based gas and the dry etching using a fluorine-based gas as a halogen gas.

### Example 5

Example 5 was carried out in the same procedures as in Example 1 except that an RhO film (film thickness: 2.5 nm) was formed as a protective film under the following conditions.

<RhO Film Formation Conditions>
Target: Rh target
Sputtering gas: mixed gas of Ar gas and O₂ (volume ratio (O₂/(Ar+O₂)) of O₂ gas in mixed gas=0.31, gas pressure: 1.5×10⁻¹ Pa)
Supplied power density per Rh target area: 3.7 W/cm²
Film formation rate: 0.073 nm/sec
The composition ratio (at %) of RhO is Rh:O=42:58.

The etching rate of the dry etching using a mixed gas of an oxygen gas and a chlorine gas as an oxygen-based gas was 1.4 nm/min, and the etching rate of the dry etching using a fluorine-based gas as a halogen gas was 5.0 nm/min. The etching selectivity to the absorption layer (RuON film) containing RuON and the etching selectivity to the absorption layer (TaN film) containing TaN are 0.030 and 0.22, respectively, which are sufficiently low to the etching rates of the respective absorption layers (RuON film and TaN film). Therefore, the RhO film has sufficient resistance to the dry etching using a mixed gas of an oxygen gas and a chlorine gas as an oxygen-based gas and the dry etching using a fluorine-based gas as a halogen gas.

### Example 6

Example 6 was carried out in the same procedures as in Example 1 except that a Ru film (film thickness: 2.5 nm) was formed as a protective film under the following conditions.

<Ru Film Formation Conditions>
Target: Ru target
Sputtering gas: Ar gas (gas pressure: 2.0×10⁻¹ Pa)
Supplied power density per Ru target area: 6.2 W/cm²
Film formation rate: 0.053 nm/sec

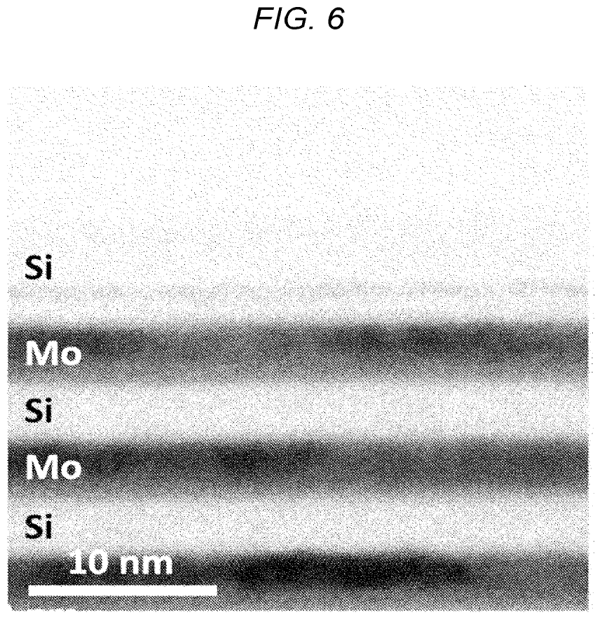

The etching rate of the dry etching using a mixed gas of an oxygen gas and a chlorine gas as an oxygen-based gas was 20.0 nm/min. The etching selectivity to the absorption layer (RuON film) containing RuON is 0.44, which is not sufficient. A sample in which the Si/Mo multilayer reflective film and the Rh film were formed on the substrate by the above procedures was etched for 60 seconds using an oxygen-based gas under the same conditions as Example 1. For each of the samples before and after the etching, the composition of a surface of the sample was analyzed using XPS. The composition before the etching was Ru:Si:Mo=89.3:9.9:1.0, and the composition of the sample after the etching was Ru:Si:Mo=3.8:92.9:3.3. The Ru film of the protective film disappeared after the etching, and there is a concern that the multilayer reflective film may be damaged. The reason why Si and Mo are detected is that the XPS detects the Si film and the Mo film serving as the base of the Ru film because an optical resolution of the XPS in a depth direction is about several nm to 10 nm. FIG. 6 shows a result of TEM observation on the sample after the etching. It was confirmed from a TEM image that the Ru protective film disappeared after the etching.

### Example 7

Example 7 was carried out in the same procedures as in Example 1 except that an RhSi film (film thickness: 2.5 nm) was formed as a protective film under the following conditions.

<RhSi Film Formation Conditions>
Target: Rh target
   Si target
Sputtering gas: Ar gas (gas pressure: 2.0×10⁻¹ Pa)
Supplied power density per Rh target area: 3.7 W/cm²
Supplied power density per Si target area: 6.9 W/cm²
Film formation rate: 0.083 nm/sec
The composition ratio (at %) of RhSi is Rh:Si=60:40.

The etching rate of the dry etching using a mixed gas of an oxygen gas and a chlorine gas as an oxygen-based gas was 1.2 nm/min, and the etching rate of the dry etching using a fluorine-based gas as a halogen gas was 7.6 nm/min. The etching selectivity to the absorption layer (TaN film) containing TaN is 0.34, which is not sufficient. Therefore, the multilayer reflective film may be damaged during etching of the absorption layer (TaN film) containing TaN.

### Example 8

In Example 8, an EUV mask blank was prepared in the same procedure as in Example 1 except that an absorption layer (RuTa film) containing RuTa was formed as an absorption layer by magnetron sputtering under the following conditions, and the following etching resistance evaluation (4) was carried out. In the following etching resistance evaluation (4), similar evaluation results are obtained in the case where a Rh film or an absorption film is formed on a silicon wafer. The film composition in each example was analyzed using an X-ray photoelectron spectroscopy (manufactured by ULVAC-PHI, Inc.).

<RuTa Film Formation Conditions>
Target: Ru target
   Ta target
Sputtering gas: Ar gas (gas pressure: 1.5×10⁻¹ Pa)
Supplied power density per target area:
   Ru: 7.5 W/cm²
   Ta: 1.2 W/cm²
The composition ratio (at %) of RuTa is Ru:Ta=82:18.
Film formation rate: 0.16 nm/sec
Film thickness: 35 nm

(4) Evaluation on Resistance to Dry Etching Using Mixed Gas of Oxygen Gas and Fluorine-Based Gas as Oxygen-Based Gas

Similar as the etching resistance evaluation (1), an ICP plasma etching was carried out under the following conditions to determine the etching rate. A sample on which an absorption layer (RuTa film) containing RuTa was formed was placed, and the etching rate was obtained by the same procedures.
ICP antenna bias: 200 W
Substrate bias: 40 W
Trigger pressure: 3.5×10⁰ Pa
Etching pressure: 3.0×10⁻¹ Pa
Etching gas: mixed gas of O₂ and CF₄

In the case where the flow rate (O₂/CF₄) was 4/28 sccm, the etching rate of the Rh protective film calculated by the etching was 1.0 nm/min. The etching rate of the absorption layer (RuTa film) containing RuTa was 31.4 nm/min. The etching selectivity of the Rh protective film to the absorption layer (RuTa film) containing RuTa is 3.3×10⁻², which is sufficiently low to the etching rate of the absorption layer (RuTa film). Therefore, the Rh protective film has sufficient resistance to the dry etching using a mixed gas of an oxygen gas and a fluorine-based gas as an oxygen-based gas.

### Example 9

Example 9 was carried out in the same procedures as in Example 8 except that an absorption layer (RuTa film) containing RuTa was formed as an absorption layer under the following conditions.

<RuTa Film Formation Conditions>
Target: Ru target
   Ta target
Sputtering gas: Ar gas (gas pressure: 1.5×10⁻¹ Pa)
Supplied power density per target area:
   Ru: 7.5 W/cm²
   Ta: 2.7 W/cm²
The composition ratio (at %) of RuTa is Ru:Ta=67:33.
Film formation rate: 0.19 nm/sec
Film thickness: 35 nm

In the case where the flow rate (O₂/CF₄) was 4/28 sccm, the etching rate of the Rh protective film calculated by the etching was 1.0 nm/min. The etching rate of the absorption layer (RuTa film) containing RuTa was 14.0 nm/min. The etching selectivity of the Rh protective film to the absorption layer (RuTa film) containing RuTa is 7.4×10⁻², which is sufficiently low to the etching rate of the absorption layer. Therefore, the Rh protective film has sufficient resistance to the dry etching using a mixed gas of an oxygen gas and a fluorine-based gas as an oxygen-based gas.

### Example 10

Example 10 was carried out in the same procedures as in Example 8 except that an absorption layer (RuTa film) containing RuTa was formed as an absorption layer under the following conditions.

<RuTa Film Formation Conditions>
Target: Ru target
   Ta target
Sputtering gas: Ar gas (gas pressure: 1.5×10⁻¹ Pa)
Supplied power density per target area:
   Ru: 7.5 W/cm²
   Ta: 4.7 W/cm²
The composition ratio (at %) of RuTa is Ru:Ta=54:46.
Film formation rate: 0.22 nm/sec
Film thickness: 35 nm

In the case where the flow rate (O₂/CF₄) was 8/24 sccm, the etching rate of the Rh protective film calculated by the etching was 1.3 nm/min. The etching rate of the absorption layer (RuTa film) containing RuTa was 27.0 nm/min. The etching selectivity of the Rh protective film to the absorption layer (RuTa film) containing RuTa is 4.8×10⁻², which is sufficiently low to the etching rate of the absorption layer (RuTa film). Therefore, the Rh protective film has sufficient resistance to the dry etching using a mixed gas of an oxygen gas and a fluorine-based gas as an oxygen-based gas.

### Example 11

Example 11 was carried out in the same procedures as in Example 8 except that an absorption layer (RuTa film) containing RuTa was formed as an absorption layer under the following conditions.

<RuTa Film Formation Conditions>
Target: Ru target
   Ta target
Sputtering gas: Ar gas (gas pressure: 1.5×10⁻¹ Pa)
Supplied power density per target area:
   Ru: 7.0 W/cm²
   Ta: 9.9 W/cm²
The composition ratio (at %) of RuTa is Ru:Ta=37:63.
Film formation rate: 0.31 nm/sec
Film thickness: 35 nm

In the case where the flow rate (O₂/CF₄) was 8/24 sccm, the etching rate of the Rh protective film calculated by the etching was 1.4 nm/min. The etching rate of the absorption layer (RuTa film) containing RuTa was 15.7 nm/min. The etching selectivity of the Rh protective film to the absorption layer (RuTa film) containing RuTa is 8.7×10⁻², which is sufficiently low to the etching rate of the absorption layer (RuTa film). Therefore, the Rh protective film has sufficient resistance to the dry etching using a mixed gas of an oxygen gas and a fluorine-based gas as an oxygen-based gas.

### Example 12

Example 12 was carried out in the same procedure as in Example 8 except that an absorption layer (RuW film) containing RuW was formed as an absorption layer using a reactive sputtering method as the magnetron sputtering method under the following conditions.

<RuW Film Formation Conditions>
Target: Ru target
   W target
Sputtering gas: Ar gas (gas pressure: 1.5×10⁻¹ Pa)
Supplied power density per target area:
   Ru: 7.5 W/cm²
   W: 0.9 W/cm²
The composition ratio (at %) of RuW is Ru:W=80:20.
Film formation rate: 0.16 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer (RuW film) containing RuW was 34.7 nm/min. The etching selectivity of the Rh protective film to the absorption layer (RuW film) containing RuW is 3.3>10⁻², which is sufficiently low to the etching rate of the absorption layer (RuW film). Therefore, the Rh protective film has sufficient resistance to the dry etching using a mixed gas of an oxygen gas and a fluorine-based gas as an oxygen-based gas.

### Example 13

Example 13 was carried out in the same procedures as in Example 12 except that an absorption layer (RuW film) containing RuW was formed as an absorption layer under the following conditions.

<RuW Film Formation Conditions>
Target: Ru target
   W target
Sputtering gas: Ar gas (gas pressure: 1.5×10⁻¹ Pa)
Supplied power density per target area:
   Ru: 7.5 W/cm²
   W: 2.0 W/cm²
The composition ratio (at %) of RuW is Ru:W=66:34.
Film formation rate: 0.18 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer (RuW film) containing RuW was 26.3 nm/min. The etching selectivity of the Rh protective film to the absorption layer (RuW film) containing RuW is 4.3×10⁻², which is sufficiently low to the etching rate of the absorption layer (RuW film). Therefore, the Rh protective film has sufficient resistance to the dry etching using a mixed gas of an oxygen gas and a fluorine-based gas as an oxygen-based gas.

### Example 14

Example 14 was carried out in the same procedures as in Example 12 except that an absorption layer (RuW film) containing RuW was formed as an absorption layer under the following conditions.

<RuW Film Formation Conditions>
Target: Ru target
   W target
Sputtering gas: Ar gas (gas pressure: 1.5×10⁻¹ Pa)
Supplied power density per target area:
   Ru: 7.5 W/cm²
   W: 3.5 W/cm²
The composition ratio (at %) of RuW is Ru:W=53:47.
Film formation rate: 0.21 nm/sec
Film thickness: 35 nm

In the case where the flow rate (O₂/CF₄) was 8/24 sccm, the etching rate of the Rh protective film calculated by the etching was 1.4 nm/min. The etching rate of the absorption layer (RuW film) containing RuW was 23.6 nm/min. The etching selectivity of the Rh protective film to the absorption layer (RuW film) containing RuW is 5.9×10⁻², which is sufficiently low to the etching rate of the absorption layer (RuW film). Therefore, the Rh protective film has a sufficient etching selectivity with respect to the RuW absorption film. Therefore, the Rh protective film has sufficient resistance to the dry etching using a mixed gas of an oxygen gas and a fluorine-based gas as an oxygen-based gas.

### Example 15

Example 15 was carried out in the same procedures as in Example 12 except that an absorption layer (RuW film) containing RuW was formed as an absorption layer under the following conditions.

<RuW Film Formation Conditions>
Target: Ru target
   W target
Sputtering gas: Ar gas (gas pressure: 1.5×10⁻¹ Pa)
Supplied power density per target area:
   Ru: 7.5 W/cm²
   W: 8.0 W/cm²
The composition ratio (at %) of RuW is Ru:W=30:70.
Film formation rate: 0.31 nm/sec
Film thickness: 35 nm

In the case where the flow rate (O₂/CF₄) was 8/24 sccm, the etching rate of the Rh protective film calculated by the etching was 1.4 nm/min. The etching rate of the absorption layer (RuW film) containing RuW was 25.6 nm/min. The etching selectivity of the Rh protective film to the absorption layer (RuW film) containing RuW is 5.5×10⁻², which is sufficiently low to the etching rate of the absorption layer (RuW film). Therefore, the Rh protective film has sufficient resistance to the dry etching using a mixed gas of an oxygen gas and a fluorine-based gas as an oxygen-based gas.

### Example 16

Example 16 was carried out in the same procedure as in Example 8 except that an absorption layer (RuCr film) containing RuCr was formed as an absorption layer using a reactive sputtering method as the magnetron sputtering method under the following conditions.

<RuCr Film Formation Conditions>
Target: Ru target
   Cr target
Sputtering gas: Ar gas (gas pressure: 1.5×10⁻¹ Pa)
Supplied power density per target area:
   Ru: 7.5 W/cm²
   Cr: 0.94 W/cm²
The composition ratio (at %) of RuCr is Ru:Cr=94:6.
Film formation rate: 0.16 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer (RuCr film) containing RuCr was 19.1 nm/min. The etching selectivity of the Rh protective film to the absorption layer (RuCr film) containing RuCr is 5.8×10⁻², which is sufficiently low to the etching rate of the absorption layer (RuCr film). Therefore, the Rh protective film has sufficient resistance to the dry etching using a mixed gas of an oxygen gas and a fluorine-based gas as an oxygen-based gas.

### Example 17

Example 17 was carried out in the same procedures as in Example 16 except that an absorption layer (RuCr film) containing RuCr was formed as an absorption layer under the following conditions.

<RuCr Film Formation Conditions>
Target: Ru target
   Cr target
Sputtering gas: Ar gas (gas pressure: 1.5×10⁻¹ Pa)
Supplied power density per target area:
   Ru: 7.5 W/cm²
   Cr: 2.1 W/cm²
The composition ratio (at %) of RuCr is Ru:Cr=86:14.
Film formation rate: 0.18 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer (RuCr film) containing RuCr was 26.5 nm/min. The etching selectivity of the Rh protective film to the absorption layer (RuCr film) containing RuCr is 4.2×10⁻², which is sufficiently low to the etching rate of the absorption layer (RuCr film). Therefore, the Rh protective film has sufficient resistance to the dry etching using a mixed gas of an oxygen gas and a fluorine-based gas as an oxygen-based gas.

### Example 18

Example 18 was carried out in the same procedures as in Example 16 except that an absorption layer (RuCr film) containing RuCr was formed as an absorption layer under the following conditions.

<RuCr Film Formation Conditions>
Target: Ru target
   Cr target
Sputtering gas: Ar gas (gas pressure: 1.5×10⁻¹ Pa)
Supplied power density per target area:
   Ru: 7.5 W/cm²
   Cr: 3.5 W/cm²
The composition ratio (at %) of RuCr is Ru:Cr=77:23.
Film formation rate: 0.21 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer (RuCr film) containing RuCr was 36.7 nm/min. The etching selectivity of the Rh protective film to the absorption layer (RuCr film) containing RuCr is 3.0×10⁻², which is sufficiently low to the etching rate of the absorption layer (RuCr film). Therefore, the Rh protective film has sufficient resistance to the dry etching using a mixed gas of an oxygen gas and a fluorine-based gas as an oxygen-based gas.

### Example 19

Example 19 was carried out in the same procedures as in Example 16 except that an absorption layer (RuCr film) containing RuCr was formed as an absorption layer under the following conditions.

<RuCr Film Formation Conditions>
Target: Ru target
   Cr target
Sputtering gas: Ar gas (gas pressure: 1.5×10⁻¹ Pa)
Supplied power density per target area:
   Ru: 7.5 W/cm²
   Cr: 8.1 W/cm²
The composition ratio (at %) of RuCr is Ru:Cr=59:41.
Film formation rate: 0.29 nm/sec
Film thickness: 35 nm

In the case where the flow rate (O₂/CF₄) was 4/28 sccm, the etching rate of the Rh protective film calculated by the etching was 1.1 nm/min. The etching rate of the absorption layer containing RuCr was 35.8 nm/min. The etching selectivity of the Rh protective film to the absorption layer (RuCr film) containing RuCr is 3.0×10⁻² which is sufficiently low to the etching rate of the absorption layer (RuCr film). Therefore, the Rh protective film has sufficient resistance to the dry etching using a mixed gas of an oxygen gas and a fluorine-based gas as an oxygen-based gas.

Although the present invention has been described in detail with reference to specific embodiments, it is apparent to those skilled in the art that various changes and modifications can be made without departing from the spirit and scope of the present invention.

The present application is based on a Japanese Patent Application (No. 2020-201198) filed on Dec. 3, 2020 and a Japanese Patent Application (No. 2021-174692) filed on Oct. 26, 2021, the contents of which are incorporated herein by reference.

### REFERENCE SIGNS LIST

1a, 1b, 1c: EUV mask blank
2: EUV mask
11: substrate
12: multilayer reflective film
13: protective film
14: absorption layer
15: diffusion barrier layer
16: etching mask film
140: absorption layer pattern

What is claimed is:

1. A reflective mask blank for EUV lithography, comprising, in the following order, a substrate, a multilayer reflective film reflecting EUV light, a protective film for the multilayer reflective film, and an absorption layer absorbing EUV light,
wherein the protective film comprises rhodium (Rh) or a rhodium material comprising Rh and at least one element selected from the group consisting of nitrogen (N), oxygen (O), carbon (C), boron (B), ruthenium (Ru), niobium (Nb), molybdenum (Mo), tantalum (Ta), iridium (Ir), palladium (Pd), zirconium (Zr), and titanium (Ti).

2. The reflective mask blank for EUV lithography according to claim 1, wherein the protective film comprises Rh and at least one element selected from the group consisting of N, O, C, and B.

3. The reflective mask blank for EUV lithography according to claim 2, wherein the protective film comprises Rh of 40 at % or more and 99 at % or less and the at least one element selected from the group consisting of N, O, C, and B of 1 at % or more and 60 at % or less.

4. The reflective mask blank for EUV lithography according to claim 1, wherein the protective film comprises Rh of 90 at % or more and has a film density of 10.0 g·cm⁻³ to 14.0 g·cm⁻³.

5. The reflective mask blank for EUV lithography according to claim 1, wherein the protective film comprises at least one element (X) selected from the group consisting of Ru, Nb, Mo, Ta, Ir, Pd, Zr, and Ti in a composition ratio (at %) (Ru:X) of Rh and X of 99:1 to 1:1.

6. The reflective mask blank for EUV lithography according to claim 1, wherein the protective film has a film thickness of 1.0 nm or more and 10.0 nm or less.

7. The reflective mask blank for EUV lithography according to claim 1, wherein the protective film comprises a surface having a surface roughness (rms) of 0.3 nm or less.

8. The reflective mask blank for EUV lithography according to claim 1, further comprising a diffusion barrier layer between the multilayer reflective film and the protective film,
wherein the diffusion barrier layer comprises at least one element selected from Nb, Ru, Ta, silicon (Si), Zr, Ti, and Mo.

9. The reflective mask blank for EUV lithography according to claim 8, wherein the diffusion barrier layer further comprises at least one element selected from the group consisting of O, N, C, and B.

10. The reflective mask blank for EUV lithography according to claim 1, wherein the absorption layer comprises at least one element selected from Ru, Ta, chromium (Cr), Nb, platinum (Pt), Ir, rhenium (Re), tungsten (W), manganese (Mn), gold (Au), Si, aluminum (Al), and hafnium (Hf).

11. The reflective mask blank for EUV lithography according to claim 10, wherein the absorption layer further comprises at least one element selected from the group consisting of O, N, C, and B.

12. The reflective mask blank for EUV lithography according to claim 1, further comprising an etching mask film on the absorption layer,
wherein the etching mask film comprises at least one element selected from the group consisting of Cr, Nb, Ti, Mo, Ta, and Si.

13. The reflective mask blank for EUV lithography according to claim 12, wherein the etching mask film further comprises at least one element selected from the group consisting of O, N, C, and B.

14. A reflective mask for EUV lithography, comprising the reflective mask blank for EUV lithography according to claim 1 and a pattern formed on the absorption layer.

15. A method for manufacturing a reflective mask blank for EUV lithography, the method comprising:
forming a multilayer reflective film reflecting EUV light on or above a substrate;
forming a protective film on or above the multilayer reflective film; and
forming an absorption layer absorbing EUV light on or above the protective film,
wherein the protective film comprises Rh or a rhodium material comprising Rh and at least one element selected from the group consisting of N, O, C, B, Ru, Nb, Mo, Ta, Ir, Pd, Zr, and Ti.

16. A method for manufacturing a reflective mask for EUV lithography, the method comprising patterning an absorption layer of a reflective mask blank for EUV lithography manufactured by the method for manufacturing a reflective mask blank for EUV lithography according to claim 15 to form a pattern.
